(19) United States
(12) Patent Application Publication
(10) Pub. No.: US 2026/0096459 A1
(43) Pub. Date: Apr. 2, 2026

(54) METHODS OF FABRICATING HYBRID GLASS CORE PACKAGE STRUCTURES INCLUDING 3D LOCKING MECHANISMS

(71) Applicant: Intel Corporation, Santa Clara, CA (US)

(72) Inventors: Seyyed Yahya Mousavi, Chandler, AZ (US); Gang Duan, Chandler, AZ (US); Jesse Jones, Chandler, AZ (US); Minglu Liu, Chandler, AZ (US); Mahdi Mohammadighaleni, Phoenix, AZ (US); Praveen Sreeramagiri, Gilbert, AZ (US); Srinivas Pietambaram, Chandler, AZ (US); Brandon Marin, Gilbert, AZ (US); Jeremy Ecton, Gilbert, AZ (US)

(73) Assignee: Intel Corporation, Santa Clara, CA (US)

(21) Appl. No.: 18/900,378

(22) Filed: Sep. 27, 2024

(51) Int. Cl. H01L 23/13; C03B 33/02; C03B 33/04; H01L 23/15; H01L 23/498

(52) U.S. Cl. CPC H10W 70/68; C03B 33/0222; C03B 33/04; H10W 70/635; H10W 70/692

(57) ABSTRACT

Microelectronic integrated circuit package structures include a package structure comprising a plurality of metal vias and a layer of glass surrounding the metal vias. The layer of glass has a first side and a second side opposite the first side, where the metal vias extend between the first side and the second side of the layer of glass. An edge sidewall is between the first side and the second side and defines a perimeter of the first side, the perimeter comprising four corners and the edge sidewall having a non-linear path from a first corner to a second corner of the four corners.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As semiconductor IC packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores can be beneficial because they can provide high density vias, provide desirable stiffness to the overall package substrate, and can improve planarity issues at the panel level.

However, glass cores are not without issue. For example, compressive stress vectors applied to the glass core by the buildup layers can result in catastrophic defects, especially at the panel level, such as SeWaRe stress defects, which can result in a horizontal splitting of the glass core or full delamination of the buildup layers from the glass.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a top view of a glass panel structure, in accordance with some embodiments.

FIG. 1B is a top view of a glass core unit, in accordance with some embodiments.

FIG. 1C is a top view of edge sidewall shapes, in accordance with some embodiments.

FIG. 1D is a cross-sectional view of edge sidewall shapes, in accordance with some embodiments.

FIG. 1E is a top view of a glass core unit, in accordance with some embodiments.

FIG. 1F is a perspective view of a glass core unit, in accordance with some embodiments.

FIG. 1G is a top view of a glass core unit, in accordance with some embodiments.

FIG. 1H is a perspective view of a glass core unit, in accordance with some embodiments.

FIG. 1I is a top view of a glass core unit, in accordance with some embodiments.

FIG. 1J is a perspective view of a glass core unit, in accordance with some embodiments.

FIG. 1K is a perspective view of a glass core unit, in accordance with some embodiments.

FIG. 2 is a top view of an integrated circuit (IC) glass panel, in accordance with some embodiments.

FIG. 3A is a top view of a glass panel structure, in accordance with some embodiments.

FIGS. 3B-3E are cross-sectional views of methods of processing glass panel structures, in accordance with some embodiments.

FIGS. 4A-4C are cross-sectional views of methods of processing glass panel structures, in accordance with some embodiments.

FIGS. 5A-5C are cross-sectional views of methods of processing glass panel structures, in accordance with some embodiments.

FIG. 5D is a top view of a glass panel structure, in accordance with some embodiments.

FIG. 6 is a cross-sectional view of an IC package structure comprising glass core units, in accordance with some embodiments.

FIGS. 7A-7B illustrate flow charts of processes for the fabrication of IC package structures having glass core units, in accordance with some embodiments.

FIG. 8 is a functional block diagram of an electronic computing device, in accordance with some embodiments of the present disclosure.

### DETAILED DESCRIPTION\

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad”and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/-10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods utilizing glass panel processing to form glass core package structures which prevent the formation of stress induced failures. For example, glass core package structures utilizing the glass panel processing methods described herein prevent the formation of stress fractures, such as SeWaRe fractures, by utilizing glass core units having non-rectilinear sidewall perimeters of different shapes. In some embodiments, the different shapes may include portions of the buildup layer in the Z direction. The glass core units with different shapes distribute and or guide energy release in the pleasant directions to prevent SeWaRe fractures, for example. Additionally, the glass core units with different edge sidewall shapes (wherein the shapes optionally include portions of the buildup layer) provide the capability of interlocking male-female edge shapes which results in an improvement of fitting adjacent glass core units together when reconstituting glass core units onto a carrier.

The embodiments described herein enable a higher yield and greater reliability of glass core package structures fabricated according to the various embodiments. The embodiments herein include methods of processing IC glass panels which enable ultra large form factor (ULFF) artificial intelligence (AI) high performance computing (HPC) packaging architectures.

The architectures described herein may be assembled and/or fabricated with one or more of the features or attributes provided in accordance with various embodiments. A number of different assembly and/or fabrication methods may be practiced to enable the formation of glass core package structures which prevent stress related fractures during processing, according to one or more of the features or attributes described herein.

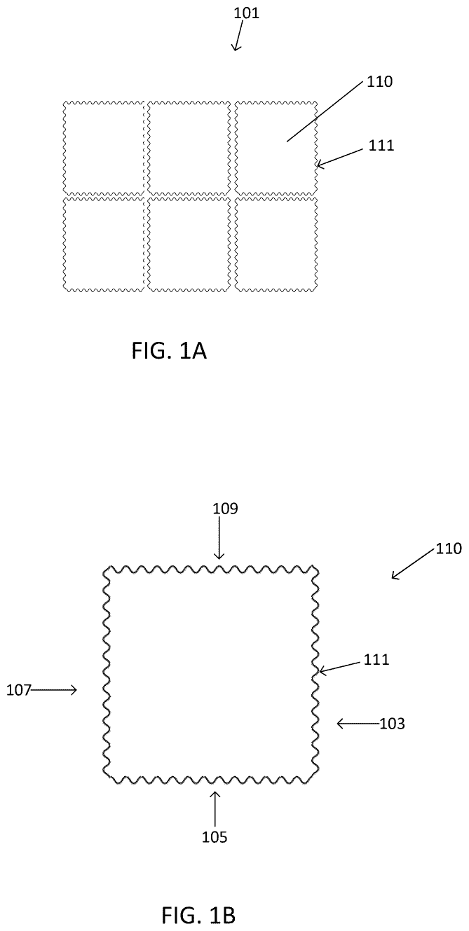

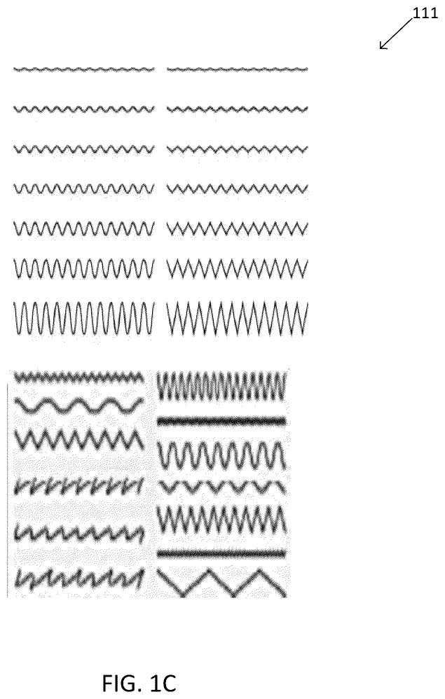

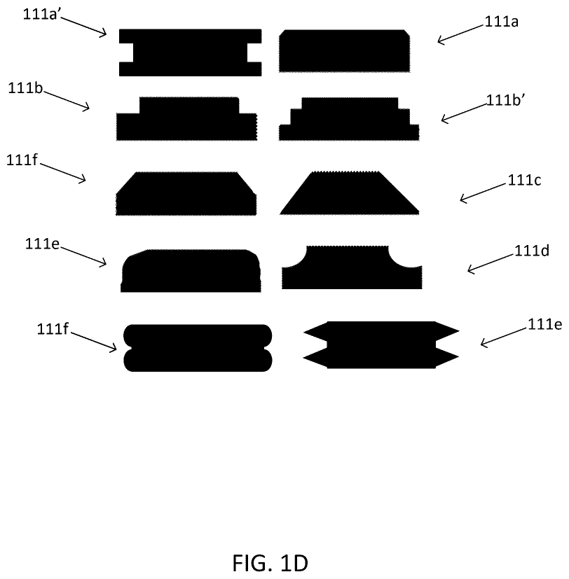

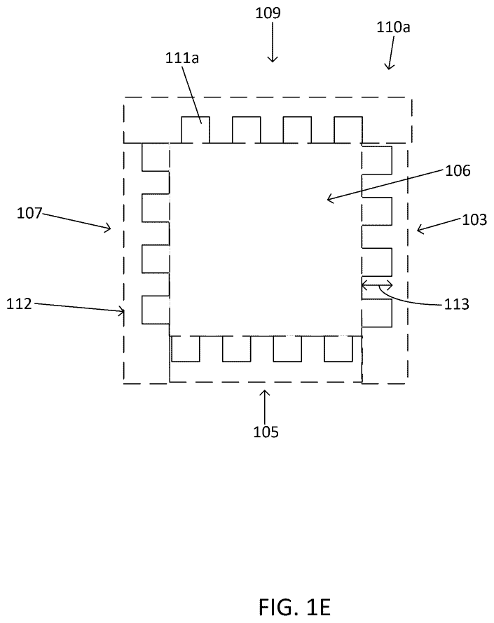

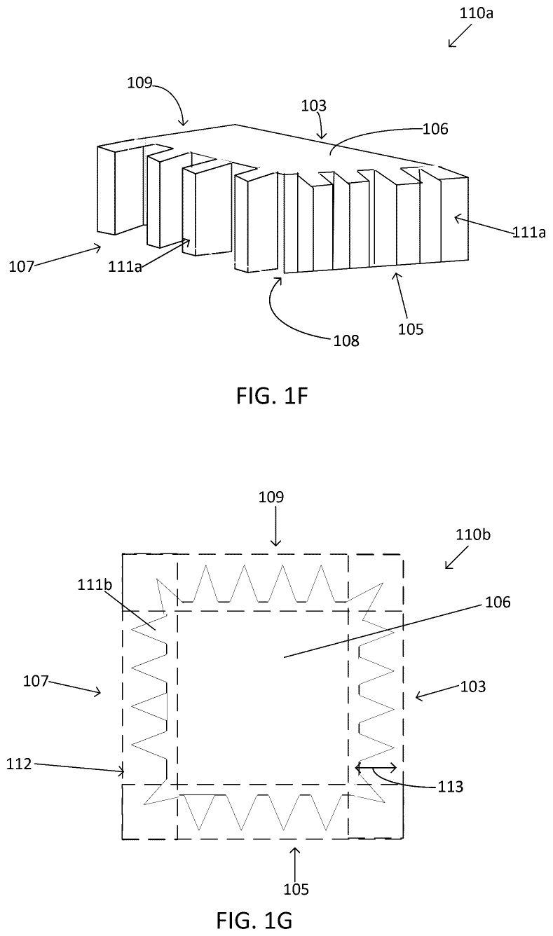

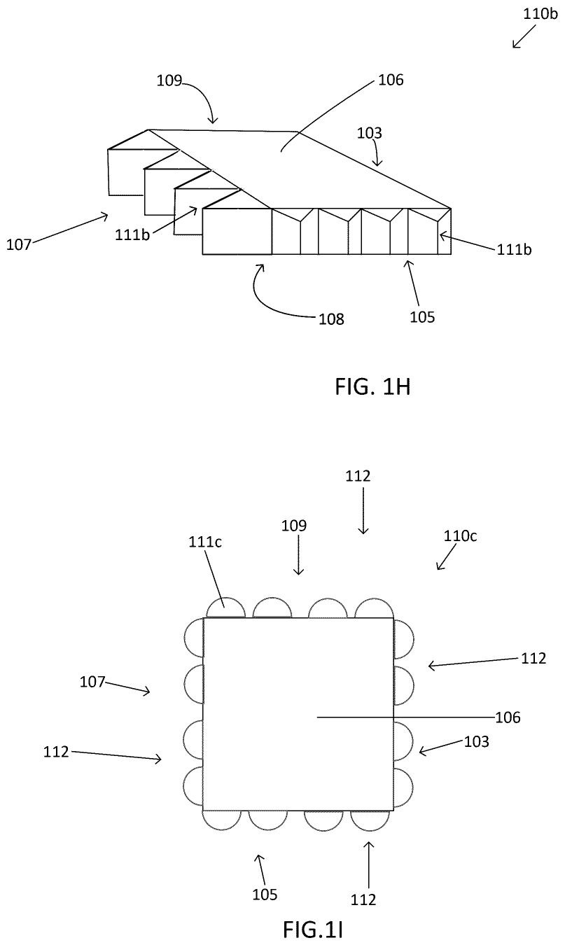

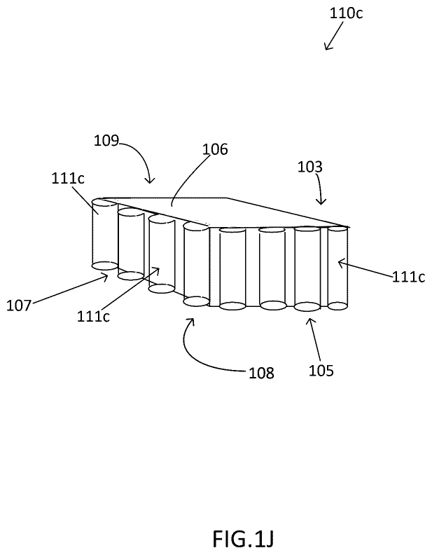

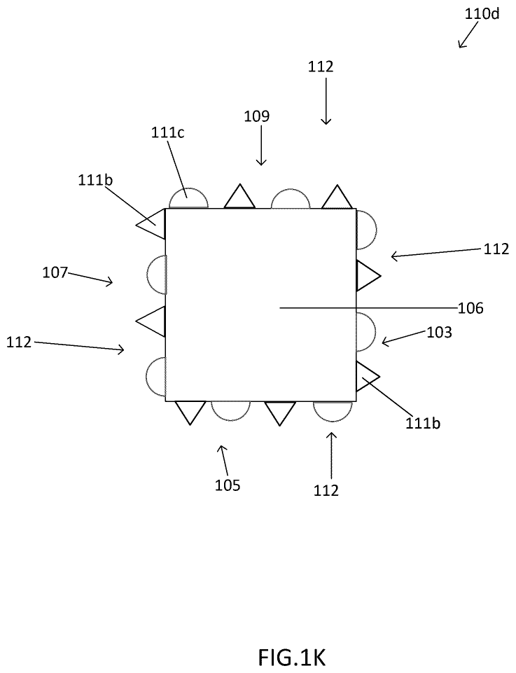

FIGS. 1A-1J illustrate embodiments of utilizing stress mitigation of the glass core, including portions of the substrate to form glass core package structures which prevent stress failures. The package structures may be formed utilizing standard IC processing techniques. The methods of fabrication described herein create improved device performance in advanced 2.5D and 3D packaging.

FIG. 1A is a top view of a portion of a glass core panel structure 101 (which may include buildup layers on top surfaces and bottom surfaces of the panel structure) comprising a plurality of glass core units 110, wherein individual glass cores 110 comprise non-rectilinear edge sidewall profiles which reduce or eliminates glass panel 101/glass core 110 stress failures. In an embodiment, the glass panel 101 may comprise a plurality of glass units 110. In an embodiment, individual glass units 110 comprise individual glass cores 110. In an embodiment, the glass panel 101 may comprise substantially all glass, or may comprise a glass layer. The glass panel 101 may be a solid material with an amorphous crystal structure. More particularly, the glass panel 101 may be any suitable glass formulation that has the necessary mechanical robustness and compatibility with semiconductor packaging manufacturing and assembly processes. For example, the glass panel 101 may comprise aluminosilicate glass, borosilicate glass, alumino-borosilicate glass, silica, fused silica, or the like. In some embodiments, the glass panel 101 may include one or more additives, such as, but not limited to, Al2O3, B2O3, MgO, CaO, SrO, BaO, SnO2, Na2O, K2O, SrO, P2O3, ZrO2, Li2O, Ti, and Zn.

More generally, the glass panel 101 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass panel 108 may comprise at least 23 percent silicon (by weight) and at least 26 percent oxygen (by weight). In some embodiments, the glass panel 108 may further comprise at least 5 percent aluminum (by weight).

In an embodiment, the glass panel 101 may have a thickness (between a first side and second side) that is between approximately 50 microns and approximately 2,000 microns, although the thickness may be optimized for the particular application. The glass panel 101 may have a substantially rectangular shape (when viewed from above in a plan view), although, other shapes may also be used for the glass panel 101.

FIG. 1B is a top view of an individual glass unit 110 comprising four edge sidewalls 103, 105, 107, 109 which may comprise any of a number of edge sidewall shapes 111. The shapes 111 extend in the X, Y and Z direction. In an embodiment, the individual shapes 111 are formed by dicing the glass units 110 to form a particular edge shape 111. FIG. 1C depicts top views of possible edge shapes 111. While FIG. 1C depicts various wave shapes 111 of different amplitudes, wavelengths and wave shapes, the embodiments herein include any other shape type as is advantageous for a particular application. Any other suitable shapes 111 may be formed according to the embodiments herein, such as a step or a series of steps, circular shapes, triangular shapes, beveled or chamfered shapes, etc.

FIG. 1D depicts cross-sectional views of examples of different shapes 111 that may be used in some embodiments, such as a chamfered shape 111a, a rectangular protrusion shape 111a′, a stepped shape 111b, a multi-stepped shape 111b′, a sloped shape 111c, a semicircular cavity shape 111d, an anvil shape 111e, a semicircle protrusion shape 111e, a beveled shape 111f, by illustration and not limitation. Referring back to FIG. 1B, the individual glass units 110 comprising the various shapes 111 increase the total edge surfaces 103, 105, 107, 109 of the glass unit 110. The increase in the edge surfaces 103, 105, 107, 109 surface areas decreases the density of residual stresses, which can limit the chance of SeWaRe formation defects. In an embodiment, the non-rectilinear edge surfaces 103, 105, 107, 109 may guide the release of the residual stresses in the desirable directions which prevents SeWaRe defects. The non-rectilinear edge surfaces 103, 105, 107, 109 propagate the release of the residual stresses in all the directions to avoid releasing stress in one single direction, which prevents SeWaRe defects. An additional advantage of the non-linear edge profiles includes the potential of physical male-female interlocking for better fitting of the glass unit units 110 during a reconstitution process, for example.

FIG. 1E depicts a top view embodiment of a glass unit 110a comprising a plurality of edge shapes 111a that may comprise rectangular shapes in an embodiment but may comprise any other shapes in another embodiment. The rectangular edge shapes 111a increase the total surface area of the edge surfaces 103, 105, 107, 109 of the glass unit 110a. The glass unit 110a comprises a top surface 106, and a bottom surface 109 (not shown). The edge sidewalls 103, 105, 107, 109 comprising the plurality of edge shapes 111a define a non-rectilinear perimeter 112 around the glass unit 110. In an embodiment, the plurality of shapes 111a may comprise any shape 111, such as any of the shapes depicted in FIGS. 1C-FIG. 1D, for example. A distance 113 may comprise between 1 micron to 5 microns but may vary depending upon the particular shape application.

FIG. 1F depicts a perspective view of the glass unit 110a depicted in FIG. 1E. Rectangular shapes 111a extend in the X, Y and Z directions of the glass unit 110a. A first side 106 of the glass unit 110a is opposite a second side 108 of the glass unit 110a.

FIG. 1G depicts a top view embodiment of a glass unit 110b comprising a plurality of triangular edge shapes 111b wherein the triangular edge shapes 111b increase the total surface area of the edge surfaces 103, 105, 107, 109 of the glass unit 110b. The glass unit 110b comprises a top surface 106, and a bottom surface (not shown). The edge sidewalls 103, 105, 107, 109 comprising the plurality of edge shapes 111b define a non-rectilinear perimeter 112 around the glass unit 110. A distance 113 may comprise between x and y but may vary depending upon the particular shape application.

FIG. H depicts a perspective view of the glass unit 110b depicted in FIG. 1G. triangular shapes 111b extend in the X, Y and Z directions of the glass unit 110b. A first side 106 of the glass unit 110b is opposite a second surface 108 of the glass unit 110b.

FIG. 1I depicts a top view embodiment of a glass unit 110c comprising a plurality of semicircular edge shapes 111c wherein the semicircular edge shapes 111c increase the total surface area of the edge surfaces 103, 105, 107, 109 of the glass unit 110c. The glass unit 110c comprises a top surface 106, and a bottom surface (not shown). The edge sidewalls 103, 105, 107, 109 comprising the plurality of edge shapes 111c define a non-rectilinear perimeter 112 around the glass unit 110c. In another embodiment, the plurality of shapes 111c may comprise any shape, such as any of the shapes depicted in FIGS. 1C-FIG. 1D, for example. A distance 113 may comprise between x and y but may vary depending upon the particular shape application.

FIG. 1J depicts a perspective view of the glass unit 110c depicted in FIG. 1I. semicircular shapes 111c extend in the X, Y and Z directions of the glass unit 110c. A first side 106 of the glass unit 110 is opposite a second surface 108 of the glass unit 110c.

FIG. 1K depicts a perspective view of the glass unit 110d, wherein semicircular shapes 111c and triangular shapes 111b extend in the X, Y and Z directions of the glass unit 110c. A first side 106 of the glass unit 110 is opposite a second surface 108 of the glass unit 110c. The glass units 110 of the embodiments herein may include any number of different shapes 111 on the same glass unit.

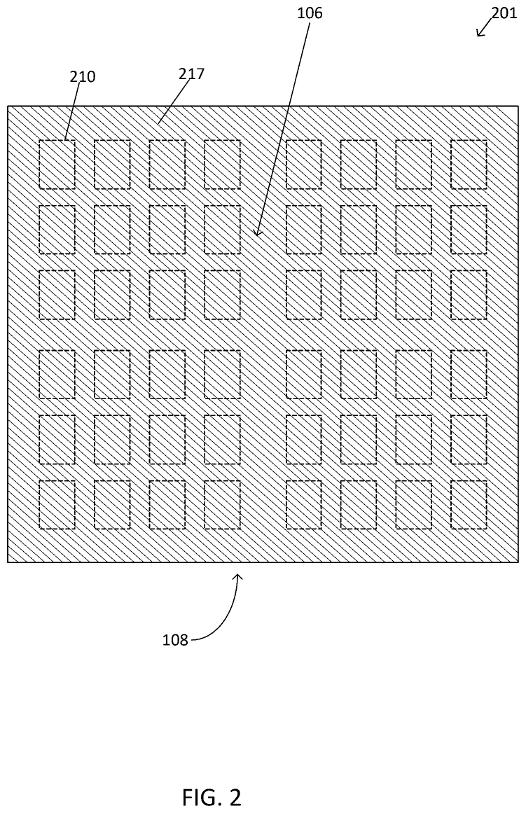

FIG. 2 illustrates a glass panel structure 201 (such as the glass panel structures 101 of FIG. 1A for example). FIG. 2 depicts a top view of the glass panel 201, in accordance with an embodiment. The glass panel 201 may include a plurality of glass package substrate units 210 that are distributed across the glass panel 201. The individual glass units 210 may be provided in a grid-like array. For example, the glass units 210 may be provided in an array that forms four quarter panels, and each quarter panel has twelve (it could be any number) individual glass units 210. The number and layout of the glass units 210 within the glass panel 201 may be varied depending on the size of the glass panel 201 and the size of the glass units 210, among other factors. The use of glass panel level processing allows for improved throughput. That is, a plurality of glass units 210 may be fabricated and assembled substantially in parallel with each other. After the glass panel 201 is completed, individual units 210 may be singulated with any suitable process. For example, a saw or other mechanical tool may cut along saw streets between the individual units 210, as well as laser processing may be employed, as is known in the art.

In the illustrated embodiment, the glass units 210 are shown with dashed lines. Dashed lines are used since, at the glass panel 210 level, the individual glass units 210 may not have any distinguishable boundary from each other. In some instances voided regions of the panel 201 (e.g., regions without electrical routing) may be provided along saw streets between the glass units 210.

Buildup layers 217 may be provided above and/or below the glass unit units 210. As described above, the interaction between the buildup layers 217 and the glass unit units 210 may result in significant warpage or other damage (e.g., SeWaRe defects). When a SeWaRe defect occurs, the forces applied to the panel result in a horizontal splitting of the glass unit. That is, the panel may split into a top side (comprising the top buildup layers and a top half of the glass unit) and a bottom side (comprising the bottom buildup layers and a bottom half of the glass unit). The top side and the bottom side warp in opposite directions of each other. Accordingly, embodiments, such as those shown in FIGS. 1A-1F may be used in order to prevent such defects.

The buildup layers 217 may be on a first side 106 and on a second side 108, opposite the first side of the glass panel 201. Buildup layers 217 may comprise a multiple-layer stack of overlaid sheets of laminated film (e.g., buildup film). Buildup layers 217 materials may include composite epoxies, liquid crystalline polymers and polyimides. Other suitable materials may be employed. In some embodiments, buildup layers 217 are a monolithic block rather than laminated film. Suitable organic or inorganic materials may be employed. Buildup layers 217 may include such materials as FR4 (e.g., epoxy-based laminate), bismaleimide-triaxine, polyimide, silicon, or epoxy resin. buildup layers 217 may comprise organic buildup film or any other dielectric material suitable for electrical packaging. The buildup layers 217 may comprise one or more laminated layers in order to form a structure with a desired thickness. In an embodiment, the buildup layers 217 may comprise electrically conductive features (e.g., pads, traces, vias, etc.) that are fabricated in conjunction with the formation of the buildup layers 217. The buildup layers 217 may include a dielectric material with conductive traces located throughout which may couple another substrate or die. The conductive traces may comprise copper or copper alloys in an embodiment.

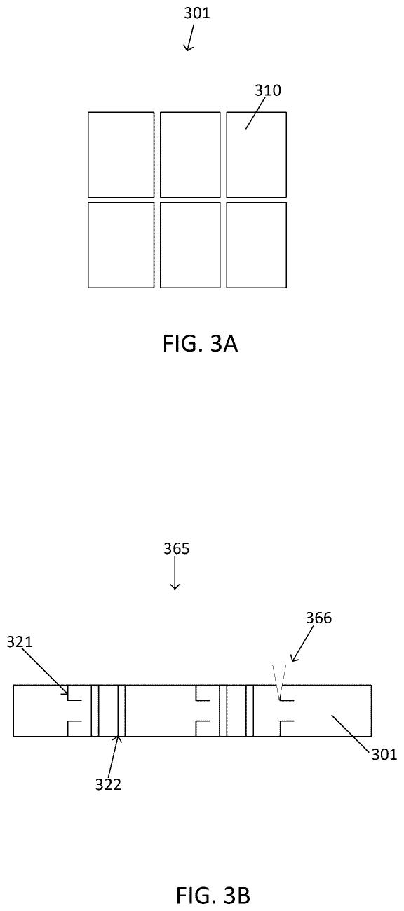

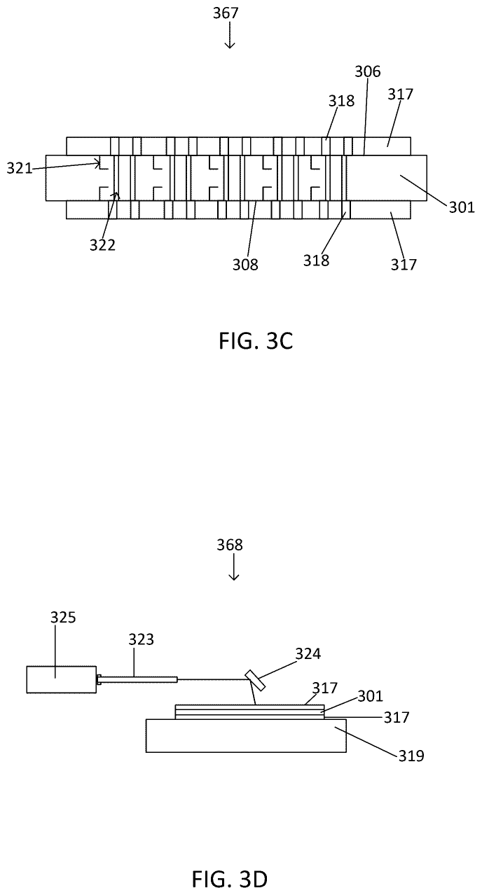

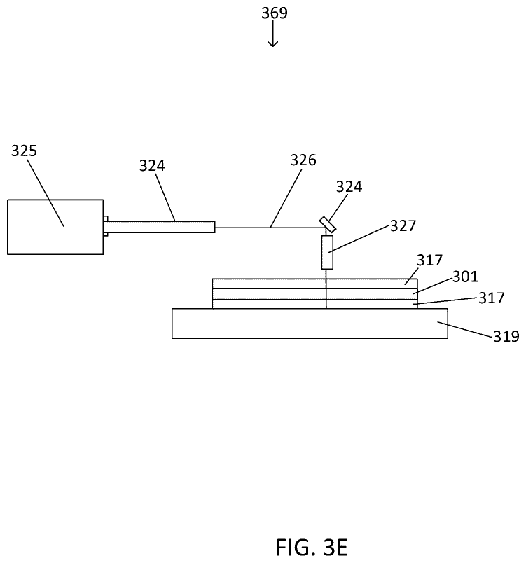

FIGS. 3A-3E depict methods of processing glass panel structures to form individual glass core package units by utilizing a dicing process, for example, where the individual glass units comprise a non-rectilinear edge shape around a perimeter of the glass unit. Some embodiments of the edge shapes are depicted in FIGS. 1C-1D however the edge shape embodiments include any shape as required by the particular application.

FIG. 3A depicts a top view of a portion of a glass panel 310 comprising a plurality of glass units 310. Each individual glass unit 310 comprises a rectilinear edge around the perimeter of the individual glass unit 310. In an embodiment, glass panel 310 may comprise a plurality of glass core units 310, a plurality of glass substrates or a glass quarter panel, wherein a plurality of package glass unit units are distributed across the glass panel 310. The individual glass unit units 310 may be provided in a grid-like array. For example, the glass unit units 310 may be provided in an array that forms four quarter panels, with each quarter panel having twelve or any number of individual units. The use of glass panel level 301 processing allows for improved throughput. That is, the plurality of glass unit units 310 may be fabricated and assembled substantially in parallel with each other.

FIG. 3B depicts a cross-sectional view of a process 365, which may comprise a nonrectilinear shape formation process in an embodiment. The nonrectilinear shape formation process 365 may initially comprise a laser dicing process in an embodiment, wherein desired nonrectilinear shapes may be formed around the perimeter of the individual glass units 310. In an embodiment, the nonrectilinear shapes may be formed in the glass panel 301 in the vertical direction initially. Formation of sidewall nonrectilinear shapes include wave guide processing and/or writing to form partial (blind) glass vias 321 in the glass panel 301.

In an embodiment, the blind glass vias 321 may be formed along glass panel 301 street locations to modify portions of glass panel 301 thickness to enable formation of the desired vertical shapes. Formation of horizontal shapes may utilize a wave guide writing process to create the desired sidewall shape. Through glass vias 322 may be formed adjacent to the blind vias 321 in an embodiment. An etching process may further be employed to achieve a desired sidewall shape. FIG. 3C depicts further processing of the glass panel 301 through the end of the production line, including utilizing a buildup formation process 367 which includes formation of buildup layers 317, including conductive traces 318 on first and second sides 306, 308 of the glass panel 301.

FIG. 3D depicts a portion of a singulation process which includes exposure of the glass panel 301 to a polymer ablation process 368. Since the glass panel 301 comprises a composite material at the singulation stage, the glass portion of the glass panel 301 may be exposed by removing any polymer that may be covering the singulation streets of the glass panel 301. In an embodiment, a laser 325 may be employed to perform a laser ablation process 368. In an embodiment, the laser ablation process 368 may comprise a wavelength selected that is based on the material being ablated from the streets. In an embodiment, a wavelength of the laser 325 may range from about 200 nm to 1100 nm, wherein the laser 325 may be shaped using a laser shaping portion 323 of the laser apparatus. A galvo scanner 324 may be employed to direct the laser energy onto the panel 301 which includes build up material 317, wherein the glass panel 301 may be on a worktable 319.

FIG. 3E depicts a perforation process 369 subsequent to an ablation process, such as the ablation process 368 of FIG. 3D wherein a laser beam 326 from a laser 325 can be directed to an exposed glass portion of the glass panel 301. In an embodiment, a filamentation/Bessel beam optic 327 can be directed along the cut lines of the glass panel 301 to modify/perforate the exposed glass along the thickness of the glass panel 301 thereby weakening the exposed glass of the glass panel 301. The individual glass units of the glass panel 301 may then be separating along the perforated zones. In an embodiment, separation may be performed by a laser or mechanical means. Upon separation, each glass unit may be ablated at desired locations to reveal the patterned nonrectilinear glass unit sidewall features, such as the nonrectilinear glass unit sidewall features depicted in FIGS. 1A-1J, for example.

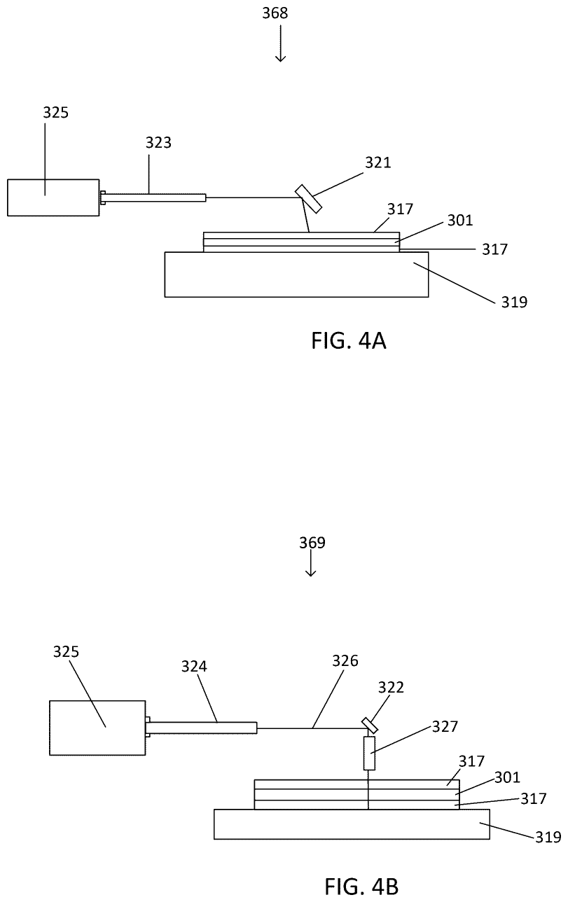

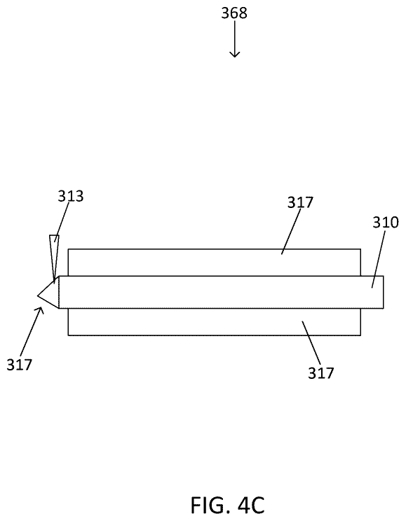

FIGS. 4A-4C depict embodiments of methods of processing glass panel structures to form nonrectilinear glass unit sidewall features along a perimeter of a glass unit edge sidewall. FIG. 4A depicts a cross-sectional view of an ablation process 368 wherein the glass panel 301 including build up layers 317 (which may be on a worktable 319) may undergo a laser ablation process (as described in FIG. 3A, for example) to expose desired glass portions of the glass panel 301 first by removing any polymer that is covering the singulation streets.

FIG. 4B depicts a perforation process 369 subsequent to the ablation process depicted in FIG. 4A wherein a filamentation/Bessel beam optic 327 from a laser 325 apparatus can be used to modify the glass portion of the glass panel 301 along a thickness of the glass panel 310 to weaken the glass portions which have been diced and etched previously, such as is depicted in FIGS. 3A-3C for example. In an embodiment, the glass units may be separated from the glass panel 301 along the perforated zones.

FIG. 4C depicts a top view of glass unit 310 including build up layers 317 after separation/singulation from the glass panel. Separation can either be performed utilizing a laser and/or mechanical process. Upon separation, glass core units 310 can be ablated on each individual unit at desired locations to reveal the desired sidewall features. In an embodiment, the individual glass units 310 may be chamfered 313 to obtain a desired edge sidewall shape.

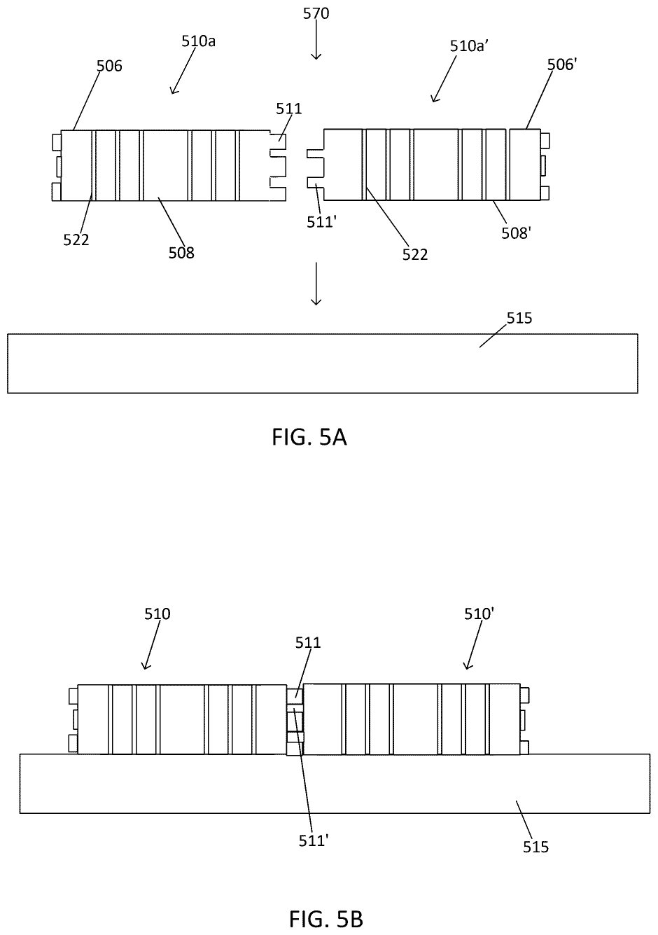

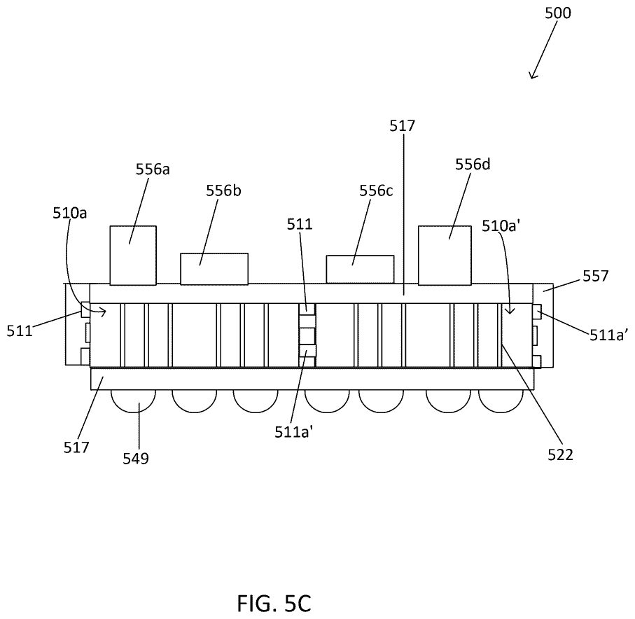

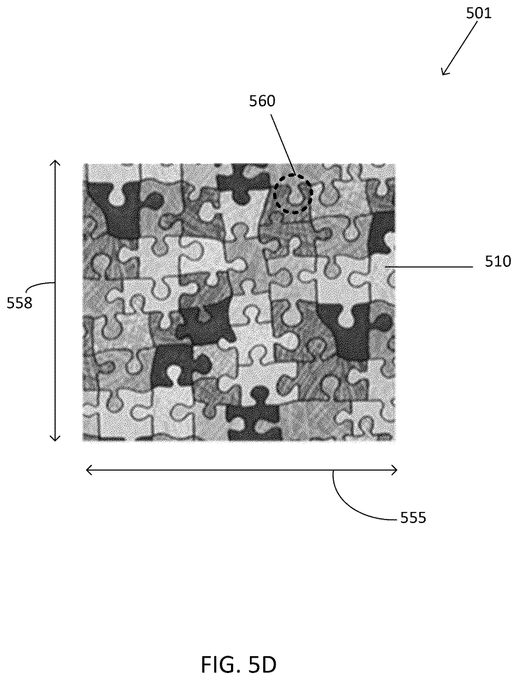

FIGS. 5A-5C depict methods of forming omni directional mechanical locking between edges sidewall of hybrid glass core package units. FIG. 5A depicts a cross-sectional view of a first glass unit 510a comprising 3D dimensional edge shapes 511a which are nonrectilinear. The nonrectilinear edge shapes 511a are similar to the nonrectilinear 3D shapes 111 of FIGS. 1E-1F for example. Through glass vias (TGVs) 522 extend between a top surface 506 and a bottom surface 508 of the first glass unit 510a. A second glass unit 510a′ comprises through glass vias (TGVs) 522 extending between a top surface 506′ and a bottom surface 508′ of the glass unit 510a. The second glass unit 510a′ comprises 3D dimensional edge shapes 511a′ which are nonrectilinear. The nonrectilinear edge shapes 511a′ of the second glass unit 511a′ are complimentary to the nonrectilinear 3D shapes 511a. That is, the edge shapes 511a, 511a′ are capable of interlocking with each other mechanically.

Interlocking process 570 may pick and place individual glass units 510a, 510a′ comprising 3D nonrectilinear edge shapes 511a, 511a′ onto a carrier 515. The interlocking nonrectilinear edge shapes 511a, 511a′ may be interlocked after being placed on the carrier in an embodiment or may be interlocked prior to placement on the carrier 515 and then after being mechanically interlocked, may be placed on the carrier 515 in another embodiment. FIG. 5B depicts the first and second glass units 510a, 510a′ interlocked between the interlocking nonrectilinear edge shapes 511a, 511a′ subsequent to placement on the carrier 515. In an embodiment, the glass units 511a, 511a′ may be reconstituted onto carrier 515.

FIG. 5C depicts a cross-sectional view of a package structure 500 comprising the first and second glass units 510a, 510a′ interlocked mechanically by complimentary nonrectilinear edge sidewall shapes 511a, 511a′. Two glass unit units are depicted however any number of interlocked glass unit units may be interlocked to form ultra large form factor package structures.

One or more dies may be coupled to the interlocked glass units 510. In an embodiment, dies 556a, 556b, 556c and 556d may comprise one or more of a high bandwidth memory die, a central processing unit, a computer die or a silicon photonics die for example, but may comprise any suitable die as are known in the art. TGV's extend from top and bottom surfaces of the glass units 510a, 510a′ and polymer material 557 may be on nonrectilinear edge shapes 511a, 511a′ in peripheral regions of the glass units 510a, 510a′. In an embodiment, the polymer material 557 may comprise such materials as epoxy material, ABF, or mold materials for example. Polymer material 557 may be utilized to provide edge protection for any of the individual glass units depicted in the embodiments herein. The vertical shapes comprising the polymer on the edges facilitate epoxy penetration inside of the thickness of the glass/substrate units and protect the unit edges from any SeWARe formation. Solder structures 549 are coupled to the dies 556a, 556b, 556c and 556d by the TGVs. In an embodiment, the package structure may comprise an ultra large form factor (ULFF) high performance computing artificial intelligence architecture. SeWaRe mitigation and reinforced edges enable improved patterning capabilities and reduced warpage.

FIG. 5D depicts a top view of a glass panel 501 wherein the glass panel comprises a length 555 and a width 558. The glass panel 501 comprises a plurality of glass units 510 wherein each individual glass unit 510 comprises a sidewall perimeter with nonrectilinear edge sidewall shapes. Each glass unit 510 is interlocked with an adjacent glass unit 510 by complimentary nonrectilinear edge sidewall shapes, such as is depicted in interlocking region for example. In an embodiment, the length 555 may comprise greater than 100 mm and the width 558 may comprise greater than 100 mm.

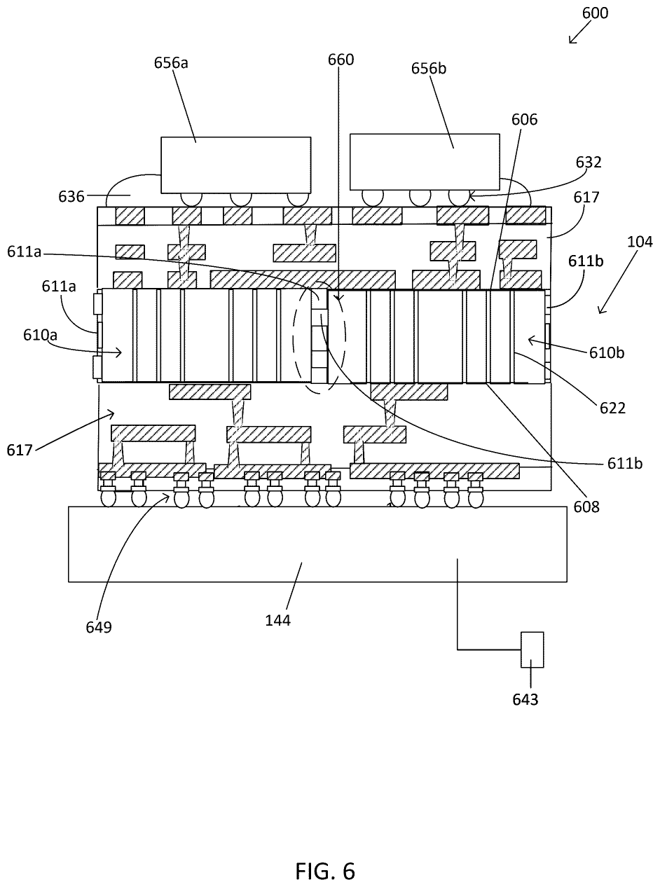

FIG. 6 depicts an IC package structure 600, such as a package structure including a first glass unit 610a and a second glass unit 610b mechanically interlocked at an interlock region 660. Each glass unit 610a, 610b is interlocked to each other by complimentary nonrectilinear edge sidewall shapes 611a, 611b, such as those depicted in FIG. 5B for example. The package structure 600 may be similar to the portions of the package structures depicted in FIG. 5C for example. Buildup layers 617 are on first and second sides 606, 608 of the glass units 610a, 610b, wherein through glass vias 622 are coupled to dies 656a, 656b. In some embodiments, the dies 656a, 656b may comprise chiplet structures which may comprise components of a system on a chip (SOC) structure. In an embodiment the glass units 610a, 610b may include a portion of an interposer. The glass units 610a, 610b may comprise nonrectilinear edge shapes around a perimeter of each glass unit 610a, 610b which extends in the x, y, and z directions. The glass units 610a, 610b provide a substrate with which to attach die and build a package structure thereupon. In an embodiment the glass units 610a, 610b may provide mechanical support and provide electrical communication.

Any number of die/devices may be coupled to the glass units 610a, 610b. A package substrate 104 (comprising the cores 610a, 610b 108 and build up layers 617) and device(s) 656a, 656b may be coupled to a board 144, such as a printed circuit board, in an embodiment. The board 144 may be coupled to the package substrate 104 through solder structures 649 in an embodiment. A power supply 643, which may comprise any suitable power supply as known in the art, may be coupled to die 656a, 656b via IC package substrate 104, in an embodiment. Solder interconnect structures 632 may couple the die 656a, 656b to the substrate 104. An underfill material 636 may surround the solder structures 632, in an embodiment.

Discussion now turns to operations for assembling and/or fabricating the discussed structures.

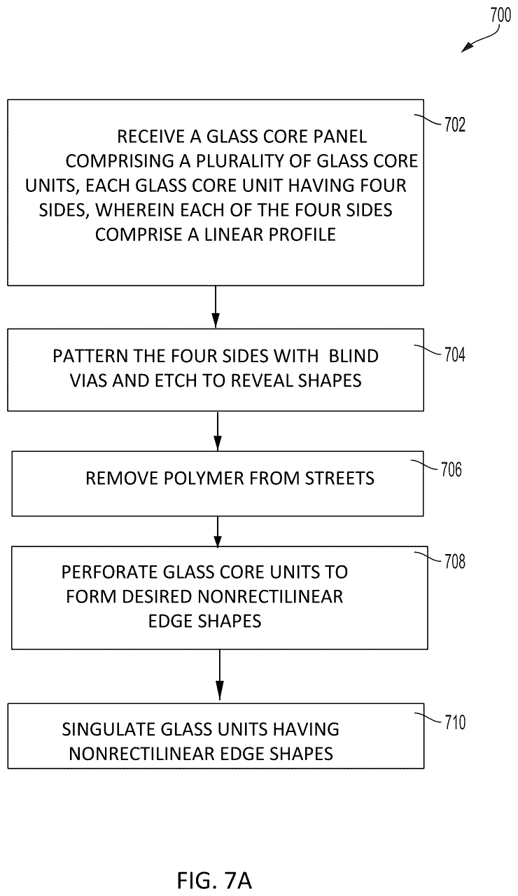

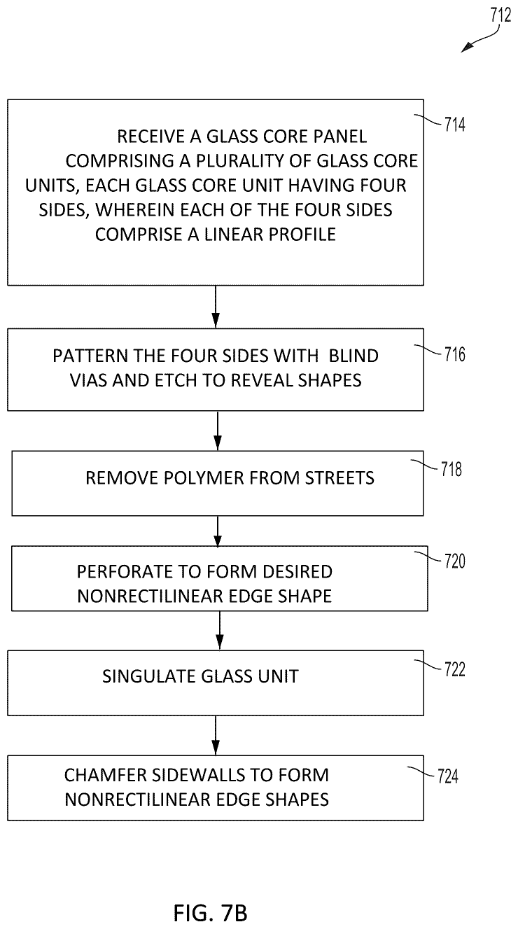

FIG. 7A is a flow chart of a process 700 of fabricating package structures, such as a package substrate comprising a glass core having a nonrectilinear sidewall profile. For example, process 700 may be used to fabricate any of the microelectronic IC package structures of FIGS. 1A-1J, for example.

As set forth in block 702, a glass core panel is received comprising a plurality of glass core units, each glass core unit having four sides, wherein each of the four sides comprise a linear profile. In an embodiment, the glass core panel may comprise a glass panel substrate as described in FIG. 2 for example comprising a plurality of glass core units which may be singulated subsequent to build up layer formation thereupon. The glass core units may comprise a layer of glass. In an embodiment, the glass layer may comprise one or more of aluminosilicate, borosilicate, an alumino borosilicate, silica, or a fused silica. In an embodiment, the layer of glass may comprise a first side and a second side opposite the first side, wherein metal vias may extend between the first side and the second side of the layer of glass. In an embodiment, the layer of glass may surround the metal vias. The metal vias may comprise through glass vias in an embodiment, wherein the metal may comprise copper or a copper alloy in an embodiment.

As set forth in block 704, the glass core units of the glass core panel may be patterned to form blind vias. In an embodiment, the glass core units may be patterned by using a laser dicing process for the x and y direction etching of desired edge sidewall patterns.

As set forth in block 706, polymer materials may be removed from the streets of the glass panel. In an embodiment, the glass layer of the glass panel may be exposed by removing any polymer from the singulation streets. This may be accomplished by utilizing a laser glass ablation process. The laser ablation process may utilize a laser with a wavelength of between 200 nm to about 1100 nm in an embodiment.

As set forth in block 708, a perforation process may be performed to form the non-rectilinear edge shapes around the edge sidewalls of individual glass core units. Upon exposing the glass along the cut lines, a filamentation/Bessel beam optical system can be used to modify the glass of the glass core unit along the sidewalls thus weakening the glass along the etched nonrectilinear edge shape patterns.

At block 710, singulation may be performed by separating the individual glass core units along the perforated zones. Separation/singulation of the glass units from the glass panel can either be done by laser or mechanical means. Subsequent to the singulation processing, the individual glass core units can be ablated at desired locations to reveal the edge sidewall nonrectilinear features. In an embodiment, the edge sidewall nonrectilinear features comprise at least one of a protrusion, a cavity, one or more steps, one or more waves, a curved profile, a sloped profile or a beveled profile, and wherein the glass core comprises a rectangular perimeter wherein each of the four sides of the rectangle comprise the non-rectilinear profile shapes in the x, y and z directions. In another embodiment, the glass core may comprise a non-rectangular perimeter, such as a circular or irregular shaped perimeter.

One or more die may be attached on the build-up layers of the glass core unit to form a package structure such as is shown in FIG. 6 for example. The die may comprise a central processing unit (CPU) or a field programmable gate array (FPGA) die, for example or may comprise any suitable logic die for the particular application. The die may be attached utilizing any suitable die attach process, as are known in the art.

By reducing compressive stress vectors applied to the glass core or the interface of the glass core and the build-up later panel by the overlying buildup layers, catastrophic defects can be reduced or eliminated especially at the panel level. SeWaRe defects may be prevented by utilizing the glass core units comprising the nonrectilinear sidewalls of the embodiments herein. Additionally, physical male-female interlocking for better fitting of the glass core units is enabled.

FIG. 7B is a flow chart of a process 712 of fabricating package structures, such as a novel hybrid approach to enable ultra large form factor (ULFF) artificial intelligence (AI) packaging architectures. Process 712 may be used to fabricate any of the microelectronic IC glass core package structures included in the embodiments herein, for example.

As set forth in block 714, a glass core panel is received comprising a plurality of glass core units, each glass core unit having four sides, wherein each of the four sides comprise a linear profile. In an embodiment, the glass core panel may comprise a glass panel substrate as described in FIG. 2 for example comprising a plurality of glass core units which may be singulated subsequent to build up layer formation thereupon. The glass core units may comprise a layer of glass. In an embodiment, the layer of glass may comprise a first side and a second side opposite the first side, wherein metal vias may extend between the first side and the second side of the layer of glass. In an embodiment, the layer of glass may surround the metal vias.

As set forth in block 716, the glass core units of the glass core panel may be patterned to form blind vias. In an embodiment, the glass core units may be patterned by using a laser dicing process for the x and y direction etching of desired edge sidewall patterns.

As set forth in block 718, polymer materials may be removed from the streets of the glass panel.

As set forth in block 720, a perforation process may be performed to form the non-rectilinear edge shapes around the sidewalls of individual glass core units.

At block 722, singulation may be performed by separating the individual glass core units along the perforated zones. Separation/singulation of the glass units from the glass panel can either be done by laser or mechanical means.

At block 724, subsequent to the singulation processing, the individual glass core units can be chamfered using a chamfering tool at desired locations to reveal the desired edge sidewall nonrectilinear features. In an embodiment, the edge sidewall nonrectilinear features comprise at least one of a protrusion, a cavity, one or more steps, one or more waves, a curved profile, a sloped profile or a beveled profile, and wherein the glass core comprises a rectangular perimeter wherein each of the four sides of the rectangle comprise the non-rectilinear profile shapes in the x, y and z directions. In another embodiment, the glass core may comprise a non-rectangular perimeter, such as a circular or irregular shaped perimeter.

One or more die may be attached on the build-up layers to form a package structure as shown in FIG. 6 for example. The die may comprise a central processing unit (CPU) or a field programmable gate array (FPGA) die, for example or may comprise any suitable logic die for the particular application. The die may be attached utilizing any suitable die attach process, as are known in the art.

The embodiments herein reduce residual stresses inside glass panels, thus avoiding issues such as SeWaRe defects. The embodiments herein distribute and guide these stresses to mitigate defects and consequent yield loss. By forming individual glass units having different sidewall shapes enables the distribution or guiding of the energy release in the pleasant directions to prevent SeWaRe occurrences. Additionally, the increase in the edge surface areas decreases the residual stress density because the stress is gathered in a larger area.

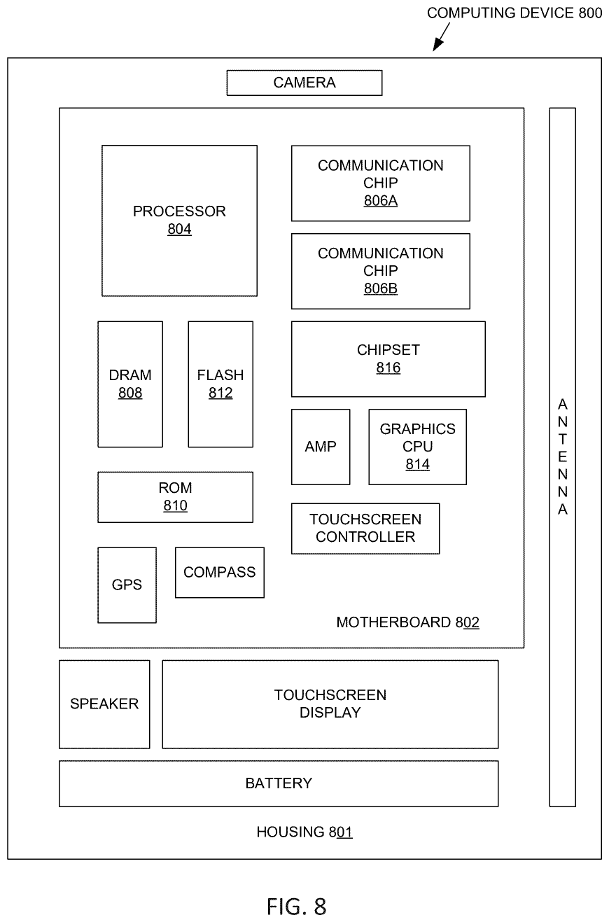

FIG. 8 illustrates an electronic or computing device 800 in accordance with one or more implementations of the present description. The computing device 800 may include a housing 801 having a board 802 disposed therein. The computing device 800 may include a number of integrated circuit components, including but not limited to a processor 804, at least one communication chip 806A, 806B, volatile memory 808 (e.g., DRAM), non-volatile memory 810 (e.g., ROM), flash memory 812, a graphics processor or CPU 814, a digital signal processor (not shown), a crypto processor (not shown), a chipset 816, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 802. In some implementations, at least one of the integrated circuit components may be a part of the processor 804.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a glass core package structure with non-rectilinear edge sidewall perimeters which may or may not be capable of interlocking with each other.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-8. The subject matter may be applied to other integrated circuit devices and assembly applications, as well as any appropriate electronic application, as will be understood to those skilled in the art.

The following examples pertain to further embodiments and specifics wherein the examples may be used anywhere in one or more embodiments, wherein a first example is an apparatus comprising a plurality of metal vias, and a layer of glass surrounding the metal vias, the layer of glass comprising: a first side and a second side opposite the first side, wherein the metal vias extend between the first side and the second side of the layer of glass, and an edge sidewall extending between the first side and the second side, wherein the edge sidewall defines a non-rectilinear perimeter of the layer of glass.

In second examples, the first example further comprises wherein the non-rectilinear perimeter comprises at least one of a protrusion or a cavity.

In third examples, the second example further comprises wherein the layer of glass comprises a glass core, wherein the glass core is over a board, and the at least one of the protrusion or the cavity extends in an x-y plane and is parallel to the board.

In fourth examples, wherein any of examples 1-3 further comprise wherein the non-rectilinear perimeter comprises at least one of one or more steps, one or more waves, a curved profile, a sloped profile, or a beveled profile, and wherein the layer of glass comprises a rectangular glass core wherein each of four sides of the rectangle comprise the non-rectilinear perimeter.

In fifth examples, wherein any of examples 1-4 further comprises wherein the non-rectilinear perimeter comprises a lateral width between 1 micron and 5 microns.

In sixth examples, wherein any of examples 1-5 further comprises wherein the plurality of metal vias comprise a plurality of through glass vias (TGVs) comprising a copper or a copper alloy, and wherein the glass layer comprises one or more of aluminosilicate, borosilicate, an alumino borosilicate, silica, or a fused silica.

In seventh examples, wherein any of examples 1-6 further comprises wherein the glass layer comprises a first glass core comprising a first non-rectilinear perimeter, wherein a second glass core comprises a second non-rectilinear perimeter, and wherein the first non-rectilinear perimeter is interlocked with the second non-rectilinear perimeter.

In eighth examples, wherein example seven further comprises wherein the first glass core is coupled to a first die and the second glass core is coupled to a second die, wherein the first glass core and the second glass core are over a board.

In ninth examples, wherein example seven further comprises wherein a plurality of glass cores comprises the first glass core and the second glass core, and wherein each non-rectilinear sidewall of the individual glass cores of the plurality of glass cores is interlocked with an adjacent non-rectilinear sidewall.

In tenth examples, wherein example nine further comprises wherein the plurality of glass cores comprise a glass panel comprising a length greater than 100 mm and a width greater than 100 mm.

In eleventh examples, wherein any of examples 1-10 further comprises further comprising a die coupled to the one or more metal vias, and a power supply coupled to the die.

Example 12 is an apparatus comprising a plurality of metal vias, and a layer of glass surrounding the metal vias, the layer of glass comprising a first side and a second side opposite the first side, wherein the metal vias extend between the first side and the second side of the layer of glass; and an edge sidewall between the first side and the second side and defining a perimeter of the first side, the perimeter comprising four corners and the edge sidewall having a non-linear path from a first corner to a second corner of the four corners.

In thirteenth examples, wherein examples 12 further comprises wherein the edge sidewall comprises at least one of a protrusion, a cavity, a step, one or more waves, a curved profile, a sloped profile or a beveled profile, and wherein the layer comprises a rectangular structure wherein each of the four sides of the rectangle comprises a plurality of shapes around a perimeter of the rectangle.

In fourteenth examples, wherein any of examples 12-13 further comprises wherein one or more die is coupled to the glass layer, wherein at least one of the one or more die comprises a 3D stacked die, a memory die or a silicon photonics die.

In fifteenth examples, wherein any of examples 12-14 further comprise wherein the glass layer comprises a plurality of glass cores wherein each individual glass core comprises a non-rectilinear sidewall that is interlocked with an adjacent non-rectilinear sidewall.

In sixteenth examples, wherein examples 15 further comprises wherein the plurality of interlocked glass cores comprises a length greater than 100 mm and a width greater than 100 mm.

Example 17 is a method comprising receiving a glass core panel comprising a plurality of glass core units, each glass core unit having a rectangular shape, wherein the rectangular shape comprises four sides, wherein each of the four sides comprise a linear profile, and wherein each of the glass core units comprises a top surface and a bottom surface, forming a non-rectilinear pattern in each of the four sides of each of the glass core units, the non-rectilinear pattern extending in an x-y plane parallel to the top and bottom surfaces, and singulating the glass core units from the glass core panel.

In eighteenth examples, wherein example 17 further comprises wherein forming the non-rectilinear pattern comprises forming at least one of a protrusion, a cavity, a step, a wave, a curve, a slope or a bevel by laser dicing and wave guide writing.

In nineteenth examples, wherein example 18 further comprises wherein singulating the glass core units comprises laser ablation.

In twentieth examples, wherein any of example 17-18 further comprises interlocking complimentary non-rectilinear sidewalls of adjacent glass core units together.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a plurality of metal vias; and
a layer of glass surrounding the metal vias, the layer of glass comprising:
a first side and a second side opposite the first side, wherein the metal vias extend between the first side and the second side of the layer of glass; and
an edge sidewall extending between the first side and the second side, wherein the edge sidewall defines a non-rectilinear perimeter of the layer of glass.

2. The apparatus of claim 1, wherein the non-rectilinear perimeter comprises at least one of a protrusion or a cavity.

3. The apparatus of claim 2, wherein the layer of glass comprises a glass core, wherein the glass core is over a board, and the at least one of the protrusion or the cavity extends in an x-y plane and is parallel to the board.

4. The apparatus of claim 1, wherein the non-rectilinear perimeter comprises at least one of one or more steps, one or more waves, a curved profile, a sloped profile, or a beveled profile, and wherein the layer of glass comprises a rectangular glass core wherein each of four sides of the rectangle comprise the non-rectilinear perimeter.

5. The apparatus of claim 1, wherein the non-rectilinear perimeter comprises a lateral width between 1 micron and 5 microns.

6. The apparatus of claim 1, wherein the plurality of metal vias comprise a plurality of through glass vias (TGVs) comprising a copper or a copper alloy, and wherein the layer of glass comprises one or more of aluminosilicate, borosilicate, an alumino borosilicate, silica, or a fused silica.

7. The apparatus of claim 1, wherein the layer of glass comprises a first glass core comprising a first non-rectilinear perimeter, wherein a second glass core comprises a second non-rectilinear perimeter, and wherein the first non-rectilinear perimeter is interlocked with the second non-rectilinear perimeter.

8. The apparatus of claim 7, wherein the first glass core is coupled to a first die and the second glass core is coupled to a second die, wherein the first glass core and the second glass core are over a board.

9. The apparatus of claim 7, wherein a plurality of glass cores comprises the first glass core and the second glass core, and wherein each non-rectilinear sidewall of the first glass core and the second glass core of the plurality of glass cores is interlocked with an adjacent non-rectilinear sidewall.

10. The apparatus of claim 9, wherein the plurality of glass cores comprise a glass panel comprising a length greater than 100 mm and a width greater than 100 mm.

11. The apparatus of claim 1, further comprising a die coupled to the plurality of metal vias, and a power supply coupled to the die.

12. An apparatus, comprising:
a plurality of metal vias; and
a layer of glass surrounding the metal vias, the layer of glass comprising:
a first side and a second side opposite the first side, wherein the metal vias extend between the first side and the second side of the layer of glass; and
an edge sidewall between the first side and the second side and defining a perimeter of the first side, the perimeter comprising four corners and the edge sidewall having a non-linear path from a first corner to a second corner of the four corners.

13. The apparatus of claim 12, wherein the edge sidewall comprises at least one of a protrusion, a cavity, a step, one or more waves, a curved profile, a sloped profile or a beveled profile, and wherein the layer of glass comprises a rectangular structure wherein each of four sides of the rectangle comprises a plurality of shapes around a perimeter of the rectangle.

14. The apparatus of claim 12, wherein one or more die is coupled to the layer of glass, wherein at least one of the one or more die comprises a 3D stacked die, a memory die or a silicon photonics die.

15. The apparatus of claim 12, wherein the layer of glass comprises a plurality of glass cores wherein each individual glass core comprises a non-rectilinear sidewall that is interlocked with an adjacent non-rectilinear sidewall.

16. The apparatus of claim 15, wherein the plurality of interlocked glass cores comprises a length greater than 100 mm and a width greater than 100 mm.

17. A method, comprising:
receiving a glass core panel comprising a plurality of glass core units, each glass core unit having a rectangular shape, wherein the rectangular shape comprises four sides, wherein each of the four sides comprise a linear profile, and wherein each of the glass core units comprises a top surface and a bottom surface;
forming a non-rectilinear pattern in each of the four sides of each of the glass core units, the non-rectilinear pattern extending in an x-y plane parallel to the top surface and the bottom surface; and
singulating the glass core units from the glass core panel.

18. The method of claim 17, wherein forming the non-rectilinear pattern comprises forming at least one of a protrusion, a cavity, a step, a wave, a curve, a slope or a bevel by laser dicing and wave guide writing.

19. The method of claim 18, wherein singulating the glass core units comprises laser ablation.

20. The method of claim 17, further comprising interlocking complimentary non-rectilinear sidewalls of adjacent glass core units together.
